(19) United States
(12) Patent Application Publication
(10) Pub. No.: US 2011/0159409 A1
(43) Pub. Date: Jun. 30, 2011

(54) DECORATED DEVICE AND METHOD OF FABRICATING THE SAME

(75) Inventors: Ming-Hung Huang, Kaohsiung City (TW); Chih-Yuan Liao, Hsinchu County (TW)

(73) Assignee: SiPix Chemical Inc., Taoyuan County (TW)

(21) Appl. No.: 12/703,738

(22) Filed: Feb. 10, 2010

(30) Foreign Application Priority Data
Dec. 30, 2009 (TW) 98145810

(51) Int. Cl. G03F 7/00

(52) U.S. Cl. 430/2

(57) ABSTRACT

A decorated device including a body, a hologram layer, and an adhesion layer and a method of fabricating the same are provided. The hologram layer is disposed on the body and includes a transparent base layer having an uneven structure and a reflective layer substantially conformable covering the uneven structure to form a plurality of holographic patterns, wherein the reflective layer is located between the adhesion layer and the transparent base layer. The adhesion layer is disposed between a surface of the body and the hologram layer.

### CROSS-REFERENCE TO RELATED APPLICATION

This application claims the priority benefit of Taiwan application serial no. 98145810, filed on Dec. 30, 2009. The entirety of the above-mentioned patent application is hereby incorporated by reference herein and made a part of specification.

### BACKGROUND OF THE INVENTION

1. Field of the Invention

The invention generally relates to a decorated device and a method of fabricating a decorated device, in particular, to a decorated device having holographic pattern decoration and a method of fabricating the same.

2. Description of Related Art

Credit cards, cashes, checks, and other important files need to have a feature of being not easy to be duplicated. The recent duplicating equipment and duplicating technique become increasingly developed, so it is also necessary to develop an updated anti-forgery technique. Hologram is a diffractive optical element, and is widely applied in authentication, security, anti-forgery, and other purposes, such as holographic pigeon pattern or holographic globe pattern on the credit cards.

The main reason is that it is impossible to forge the hologram by means of scanning or printing, and it is not easy to forge in a holographic manner except for the experts familiar with the holographic technique. Presently, the holographic patterns are formed on a paper or a film sheet to construct a tag or a mark. The tag or the mark is adhered on a device so as to accomplish the anti-forgery design. However, the adhesion of the tag or the mark on the device is not reliable because the adhesion material may be deteriorated through the weathering, the oxidation, or the like so that the tag or the mark may be peel-off from the device. In addition, the hologram may easily scrapped or damaged.

### SUMMARY OF THE INVENTION

Accordingly, the invention is directed to a decorated device having holographic patterns.

The invention is also directed to a method of fabricating a decorated device having holographic patterns.

The invention provides a decorated device including a body, a hologram layer, and an adhesion layer. The hologram layer is disposed on the body and includes a transparent base layer having an uneven structure and a reflective layer substantially conformable covering the uneven structure to form a plurality of holographic patterns, wherein the reflective layer is located between the adhesion layer and the transparent base layer. The adhesion layer is disposed between a surface of the body and the hologram layer.

In a decorated device according to an embodiment of the invention, the surface is a non-plane surface and the hologram layer is conformed to the non-plane surface.

In a decorated device according to an embodiment of the invention, the transparent base layer is a releasing layer.

In a decorated device according to an embodiment of the invention, the transparent base layer is a durable layer.

In a decorated device according to an embodiment of the invention, an ink layer is further disposed between the transparent base layer and the adhesion layer.

In a decorated device according to an embodiment of the invention, a material of the reflective layer includes Al, Cu, Ni, Zn, Cr, Ag, Ti, W, Au, Pt, Pb, Sn, Mg, metal oxide, alloy oxide or any combination thereof.

The invention also provides a method of fabricating a decorated device. First, a hologram layer having a plurality of holographic patterns is formed on a substrate. An adhesion layer is formed on the hologram layer away from the substrate. Thereafter, a body is formed by a decoration process so that the hologram layer is conformably adhered on a surface of the body through the adhesion layer.

In a method of fabricating a decorated device according to an embodiment of the invention, the method of forming the hologram layer on the substrate includes: forming a transparent base layer on the substrate; performing a pattern transferring process on the transparent base layer to form an uneven structure away from the substrate; and forming a reflective layer on the transparent base layer and the reflective layer conformably covering the uneven structure. In an embodiment, the method of performing a pattern transferring process on the transparent base layer includes performing an embossing process on the transparent base layer to form the uneven structure away from the substrate. In addition, the method of forming the reflective layer on the uneven structure includes performing an evaporation coating process or a sputtering process. It is noted that the reflective layer can be formed after forming the uneven structure on the transparent base layer. Alternatively, the reflective layer is formed before forming the uneven structure on the transparent base layer. Specifically, the method of fabricating a decorated device further includes: forming a mask layer on the base layer to expose a portion of the uneven structure before forming the reflective layer; and removing the mask layer after forming the reflective layer so that the reflective layer covers a portion of the uneven structure.

In a method of fabricating a decorated device according to an embodiment of the invention, the method of the decoration process includes: putting the substrate and the hologram layer disposed thereon in a fixture; filling a body material in the fixture; ejecting the body and the hologram layer from the fixture; and separating the substrate from the hologram layer. For example, the body material includes a plastic material. In an embodiment, the substrate is separated from the hologram layer simultaneously when the body and the hologram layer are ejected. Nevertheless, the substrate may be separated from the hologram layer after the body and the hologram layer are ejected.

In a method of fabricating a decorated device according to an embodiment of the invention, the decoration process includes adhering the hologram layer on the surface of the body through performing an in-mold rolling process.

In a method of fabricating a decorated device according to an embodiment of the invention, an ink layer is further formed on the hologram layer before forming the adhesion layer.

In a method of fabricating a decorated device according to an embodiment of the invention, a releasing layer is further formed on the substrate before forming the hologram layer so that the releasing layer is located between the hologram and the substrate. In addition, after forming the body, the substrate and the releasing layer are further separated from the hologram layer. Herein, the transparent base layer can be a durable layer.

In view of the above, the hologram layer having holographic patterns is formed on a body of a device through the in-mold decoration technique. Therefore, the holographic patterns are prevented from being damaged to extent the lifetime and improve the reliability of the hologram layer. Accordingly, the hologram layer provides superior anti-forgery function.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E schematically illustrate a method of fabricating a decorated device according to an embodiment of the invention.

FIG. 2A to FIG. 2D schematically illustrate a method of fabricating a decorated device according to another embodiment of the invention.

FIGS. 3A to 3D illustrate a method of forming a decorated device having a partial holographic pattern.

FIG. 4A and FIG. 4B schematically illustrate a partial process of a method of fabricating a decorated device according to further another embodiment.

FIG. 5A illustrates a schematic cross sectional view of a decorated device according to further another embodiment.

FIG. 5B illustrates a schematic top view of a complex holographic pattern.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

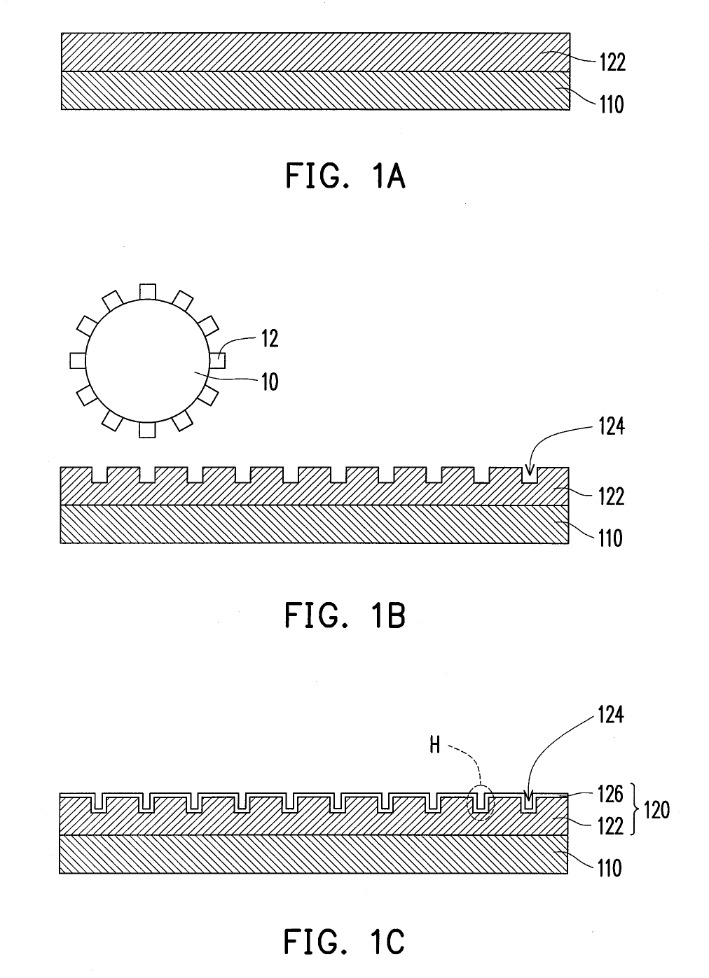

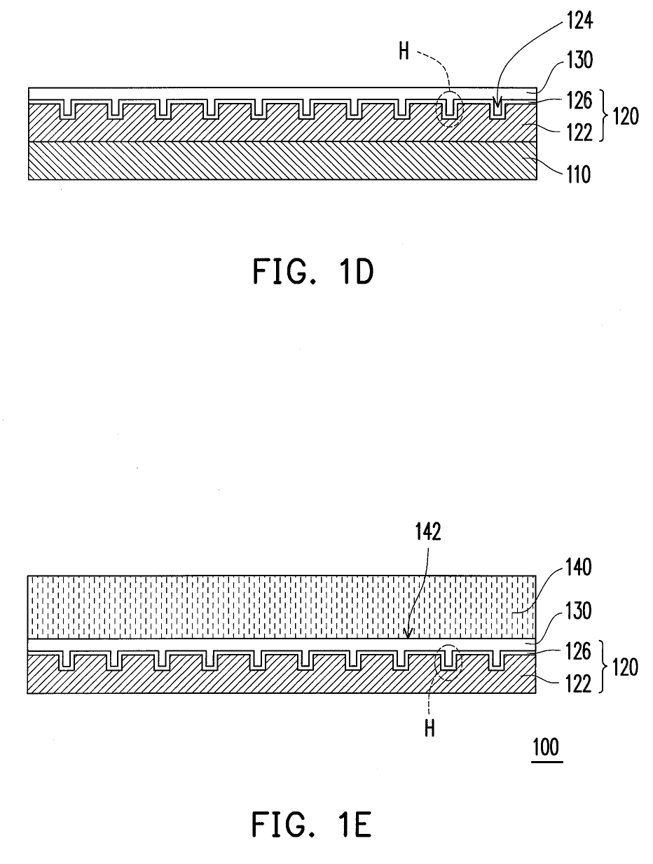

FIG. 1A to FIG. 1E schematically illustrate a method of fabricating a decorated device according to an embodiment of the invention. First, referring to FIG. 1A, a releasing layer 122 is formed on a substrate 110. The method of forming the releasing layer 122 on the substrate 110 can be performing a coating process to coat a transparent material on the substrate 110. In the present embodiment, a material of the substrate 110 can be polycarbonate (PC), polyethylene terephthalate (PET), or other polymer substrate materials, and particularly the substrate 110 is flexible. Specifically, the material of the substrate 110 can further be polyethylene naphthalate (PEN), polyethylene glycol-co-cyclohexane-1,4 dimethanol terephthalate (PETG), thermalplastic polyurethane (TPU), polyurethane (PU), polypropylene (PP), amorphous polyethylene terephthalate (A-PET), polyvinyl chloride (PVC), Polystyrene (PS), triacetyl cellulose (TAC), polymethylmethacrylate (PMMA), MMA-St, MS, cyclo olefin copolymer (COC), other polymer or a combination thereof. However, the material of the substrate 110 is not restricted herein. In addition, a material of the releasing layer 122 can be a transparent resin material having thermal curable or UV (ultra violate light) curable property. The releasing layer 122 can be formed from wax, paraffin or silicone or a highly smooth and impermeable coating prepared from a radiation curable multifunctional acrylate, silicone acrylate, epoxide, vinyl ester, vinyl ether, allyl or vinyl, unsaturated polyester or a blend thereof.

Next, referring to FIG. 1B, a pattern transferring process such as an embossing process is performed on the releasing layer 122. During the embossing process, a roller 10 having a plurality of protrusion patterns 12 is used for contacting and pressing the releasing layer 122 so that the protrusion patterns 12 are transferred on the releasing layer 122 to form an uneven structure 124. The uneven structure 124 is located at the side of the releasing layer 122 away from the substrate 110 in the present embodiment. It is noted that the protrusion patterns 12 are fabricated according to optical interference stripes of a determined image. In addition, the roller 10 illustrated in FIG. 1B can be replaced by a plat having the protrusion patterns 12 for transferring the optical interference stripes of the determined image on the releasing layer 122. Specifically, the embossing process may be a hot embossing process or other process commonly used in the art, and the invention is not limited herein. Namely, the formation of the uneven structure 124 is not restricted in the illustration shown in FIG. 1B. In addition, the releasing layer 122 is cured by heating or UV irradiating so as to provide a fixed pattern. In the embodiment, the releasing layer 122 has a thickness of 1-30 μm.

Next, a reflective layer 126 is formed on the uneven structure 124 as shown in FIG. 1C so that a hologram layer 120 is formed. The method of forming the reflective layer 126 can be an evaporation process or a sputtering process. The reflective layer 126 is substantially conformal to the uneven structure 124 so that a light reflected by the reflective layer 126 can show a hologram image by an interference effect. Therefore, the uneven structure 124 and the reflective layer 126 covering thereon can define a plurality of holographic patterns H in the hologram layer 120. In an embodiment, a material of the reflective layer 126 can be Al, Cu, Ni, Zn, Cr, Ag, Ti, W, Au, Pt, Pb, Sn, Mg, metal oxide, alloy oxide or any combination thereof.

Thereafter, referring to FIGS. 1D and 1E, an adhesion layer 130 is formed on the reflective layer 126 to facilitate to the adhesion of the hologram layer 120 on a body 140 of a device 100. The adhesion layer 130 can be formed from polyacrylate, polymethacrylate, polystyrene, polycarbonate, polyurethane, polyester, polyamide, epoxy resin, ethylene vinylacetate copolymer (EVA) or thermoplastic elastomer or a copolymer, blend or composite thereof. Specifically, the substrate 110 can be subsequently removed so that the device 100 having the hologram layer 120 is formed. It is noted that the holographic patterns H are sandwiched between the releasing layer 122 and the body 140. Therefore, the holographic patterns H are not easily contacted by ambient materials. Accordingly, the holographic patterns H are not damaged easily so as to have high reliability.

Specifically, the method of forming the body 140 of the device 100 can be a decoration process. The decoration process can be performed by the following steps. First, the substrate 110 and the hologram layer 120 disposed thereon are placed in a fixture (not shown). In the present step, the fixture (not shown) can be a mold for fabricating the body 140. Then, a body material is filled in the fixture (not shown) and subsequently the body 140 and the hologram layer 120 are ejected from the fixture (not shown). Herein, the substrate 100 is separated from the hologram layer 120 simultaneously when the body 140 and the hologram layer 120 are ejected. Nevertheless, the substrate 110 may be separated from the hologram layer 120 after the body 140 and the hologram layer 120 are ejected in other embodiments. Based on the above steps, the in-mold process is performed. In an example, the body material can be a plastic material such as polycarbonate (PC), polypropylene (PP), polymethylmethacrylate (PMMA), MMA-St, MS, acrylonitrile butadiene styrene (ABS), polystyrene (PS), polyethylene terephthalate (PET), polyoxymethylene (POM) or a combination thereof, but are not restricted herein. The above-mentioned process can be a conventional injection molding process used in the art. Nevertheless, the decoration process of the present embodiment is not restricted in the above-mentioned process; the decoration process can also be an in-mold rolling process, laminating process, thermoforming process, blow molding process, stamping process, compression molding process, or a combination thereof so as to combine the hologram layer 120 to the body 140 of the device 100.

In the present embodiment, the body 140 of the device 100 is configured with the hologram layer 120, and the holographic patterns H are sandwiched between the releasing layer 122 and the adhesion layer 130. Therefore, the holographic patterns H are protected from scraping and damaging. Specifically, after using the device 100 for a long time, the holographic patterns H are still clear and can be easily distinguished. If the holographic patterns H are used as an anti-forgery mark, the holographic patterns H can provide a desirable and reliable anti-forgery effect. In addition, the hologram layer 120 of the present embodiment is fabricated through the decoration process to be combined with the body 140 so that the hologram layer 120 can be conformed to a surface 142 of the body 140. No matter the shape of the body 140 is, the hologram layer 140 can be formed thereon. Namely, the hologram layer 120 can be tightly adhered on any surface such a plane surface, a curved surface, a rugged surface, or a stingy surface so that the utility convenience of the hologram layer 120 is largely enhanced. Accordingly, the design of the device 100 having the holographic patterns H can be variety.

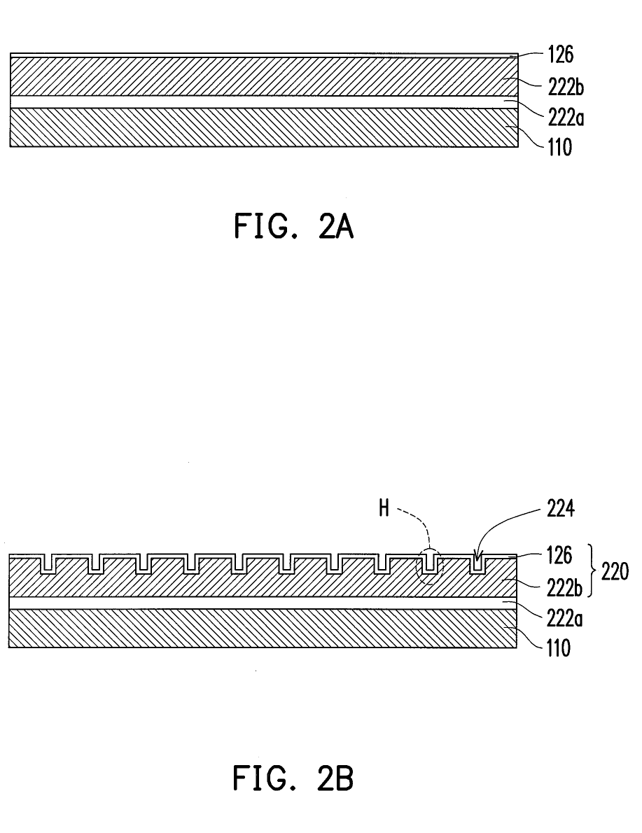

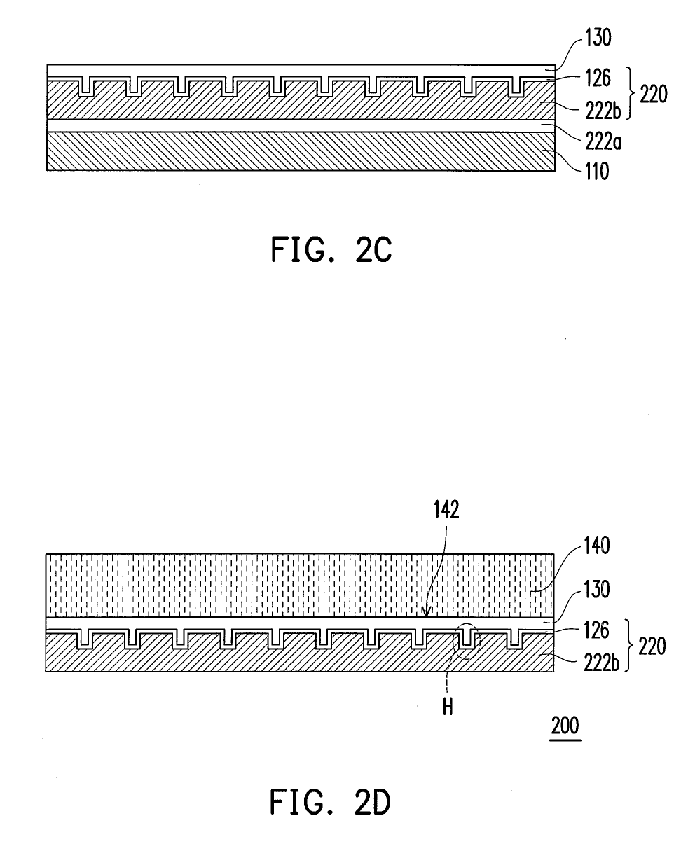

FIG. 2A to FIG. 2D schematically illustrate a method of fabricating an decorated device according to another embodiment of the invention. Referring to FIG. 2A, in the present embodiment, a releasing layer 222a and a durable layer 222b, and a reflective layer 126 are sequentially formed on a substrate 110. The substrate 110 can be selected from a PC substrate, a PET substrate, or the like. A material of the reflective layer 126 can be Al, Cu, Ni, Zn, Cr, Ag, Ti, W, Au, Pt, Pb, Sn, Mg, metal oxide, alloy oxide or any combination thereof. Herein, the releasing layer 222a is used for temporally connecting the durable layer 222b and the substrate 110 and is going to be separated from the durable layer 222b in the subsequent process. The durable layer 222b can be a thermal curing material layer or an UV (ultra violate light) curable material layer, i.e. a material of the durable layer 222b can be a thermal curing resin, an UV irradiated reaction resin or the like. Generally, a material of the releasing layer 222a can be siloxane or silicone, for example, so as to provide the temporal adhesion effect. In one embodiment, the durable layer 222b has a thickness of 1-30 μm.

Thereafter, referring to FIG. 2B, a pattern transferring process is performed on the substrate 110 to form a hologram layer 220. In the process, an uneven structure 224 is formed on a surface (not marked) of the durable layer 222b and the reflective layer 126 is conformed to the uneven structure 224. Specifically, the pattern transferring process can be an imprinting process or a hot embossing process, for example. Similar to the aforesaid embossing process, a plate or a roller having a plurality of protrusion patterns fabricated according to optical interference stripes of a determined image is used for transferring patterns in the present step. That is to say, the uneven structure 224 and the reflective layer 126 covered thereon together construct a plurality of holographic patterns H.

Next, referring to FIGS. 2C and 2D simultaneously, an adhesion layer 130 is formed on the hologram layer 220 and a decoration process is performed so as to complete the device 200 illustrated in FIG. 2D. The decoration process of the present embodiment can be referred to the aforementioned embodiment. Namely, the substrate 110 configured with the releasing layer 222a, the hologram layer 220, and the adhesion layer 130 can be put in a fixture, and a melted plastic material can be fill into the fixture. Therefore, the hologram layer 220 is tightly disposed on a surface 142 of a body 140 of the device 200. Next, an ejection process is performed, and the substrate 110 and the releasing layer 222a can be separated from the hologram layer 220. It is noted that the configuration of the releasing layer 222a facilitates the separation of the substrate 110 from the hologram layer 220 in the present embodiment. Specifically, the device 200 can also be formed by performing an in-mold rolling process to combine the hologram layer 220 to the body 140.

In the present embodiment, the decoration process is conducive to tightly connect the hologram layer 220 to the surface 142 of the body 140 through the adhesion layer 130 so that the hologram layer 220 has high reliability. In an embodiment, the hologram layer 220 can be embedded in the body 140 through the decoration process and the holographic patterns H are sandwiched between the durable layer 222b and the body 140. Accordingly, the holographic patterns H are difficultly scrapped and damaged. Furthermore, the hologram layer 220 is conformed to the surface 142 of the body 140 so that the surface 142 can be a plane surface or a non-plane surface. Consequentially, compared with the conventional design which additionally adhere a paper with holographic patterns on a plane surface of a device, the design of the device 200 can be variety and the hologram layer 220 of the present embodiment has better reliability.

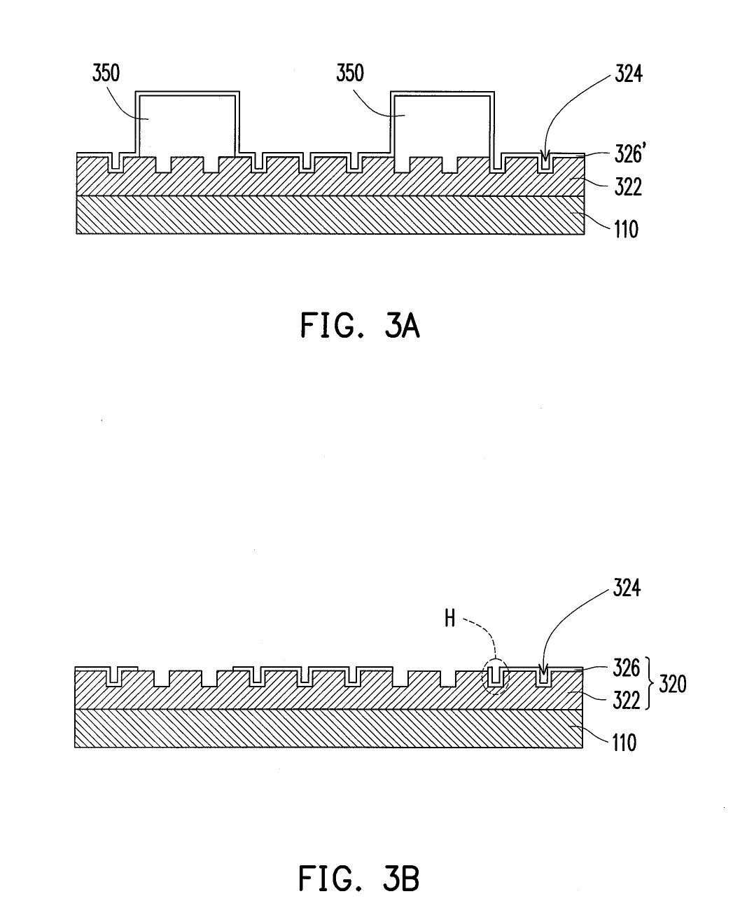

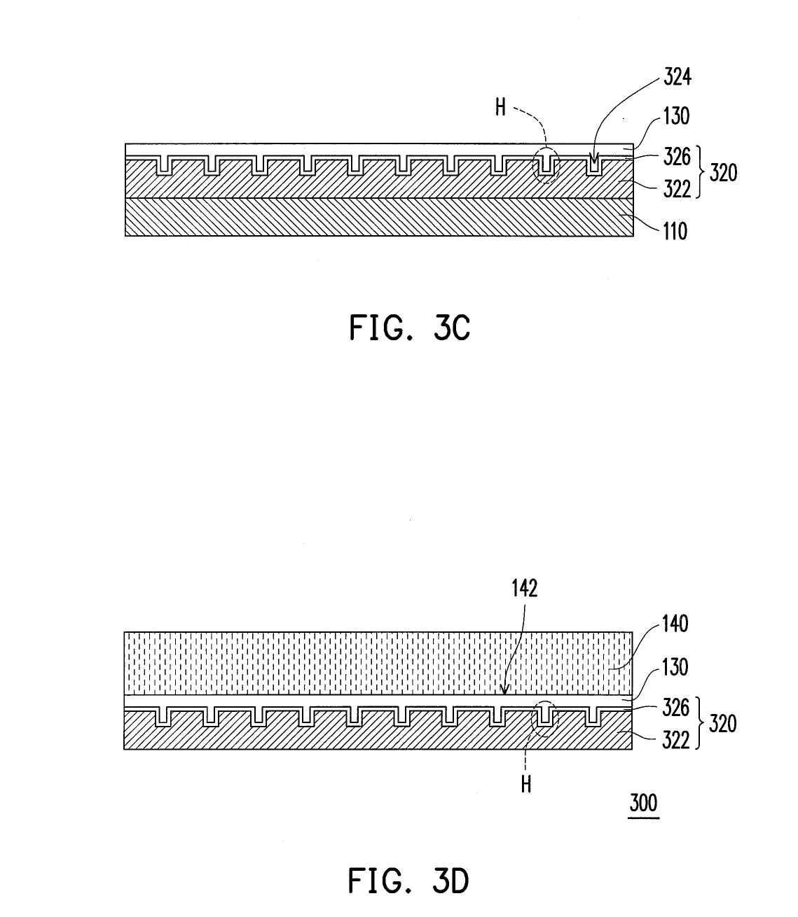

In other embodiments, the reflective layer 126 can be partially formed on the substrate 110 so as to fabricate a partial holographic pattern. In particular, FIGS. 3A to 3D illustrate a method of forming a decorated device having a partial holographic pattern. Referring to FIG. 3A, a substrate 110 and a transparent base layer 322 disposed thereon are provided. Herein the transparent base layer 322 can be fabricated through the process mentioned-above so as to have an uneven structure 324. In addition, a releasing layer (not shown) can be disposed between the transparent base layer 322 and the substrate 110 as that illustrated in FIG. 2B or the transparent base layer 322 can be a releasing layer itself. Specifically, in the present process, a mask layer 350 is formed on the transparent base layer 322 to cover a portion of the surface of the transparent base layer 322. The mask layer 350 may be made of a polymeric material including polyurethane (PU), polymethylmethacrylate (PMMA), epoxide, polyester, or the combination of the abovementioned materials. Thereafter, a reflective material layer 326′ is formed on the substrate 110 through an evaporation coating process or a sputtering process. In the present embodiment, the reflective material layer 326′ conformably covers another portion of the transparent base layer 322 exposed by the mask layer 350 and the mask layer 350.

Then, referring to FIG. 3B, the mask layer 350 is removed to form the reflective layer 326 partially exposes the transparent base layer 322. In the present embodiment, the reflective layer 326 and the uneven structure 324 together form a plurality of holographic patterns H. The reflective layer 326 is partially disposed on the substrate so that the holographic patterns H are partially configured in the hologram layer 320. Then, referring to FIGS. 3C and 3D, an adhesive layer 130 is formed on the hologram layer 320, and subsequently the decoration process mention in the aforesaid embodiment is performed to fabricate a device 300 having a body 140 and the hologram layer 320 thereon. The present embodiment is similar to the aforesaid embodiment, which provides the hologram layer 320 disposed on the body 140 through the adhesive layer 130. However, the holographic patterns H are partially distributed on the surface of the body 140 so as to enhance the variety of the design of the body 140.

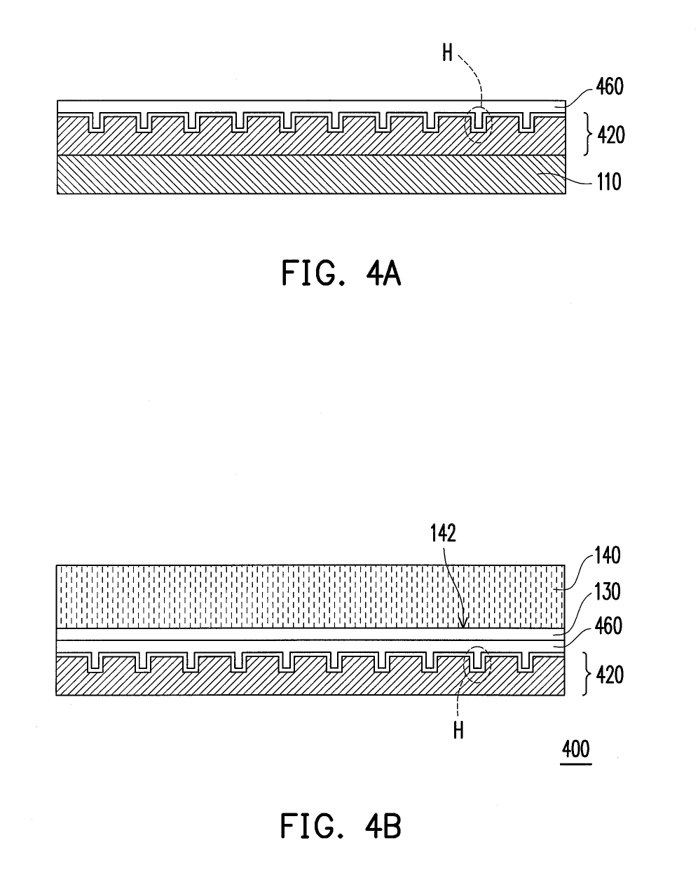

Specifically, in addition to the holographic patterns, some other patterns such as ink patterns can be form on the surface of the device, and the related fabricating process is schematically shown in FIGS. 4A and 4B. FIG. 4A and FIG. 4B schematically illustrate a partial process of a method of fabricating a decorated device according to further another embodiment. Referring to FIG. 4A, a substrate 110 and a hologram layer 420 disposed thereon are provided. Herein, the hologram layer 420 can be the aforementioned hologram layers 120, 220, or 320. That is to say, the hologram layer 420 can be fabricated through the process mentioned-above, and a releasing layer (not shown) can be disposed between the hologram layer 420 and the substrate 110 as that illustrated in FIG. 2B. In addition, an ink layer 460 is formed on the hologram layer 420. The ink layer 460 can be a colourful ink layer, a black ink layer, or a white ink layer so as to form an ink pattern.

Next, referring to FIG. 4B, the hologram layer 420 and the ink layer 460 are adhered on a body 140 of a device 400 through a decoration process. Specifically, the hologram layer 420 and the ink layer 460 are adhered on the body 140 through an adhesion layer 130. The decoration process can be referred to the above-mentioned process so that the device 400 can be formed by simultaneously ejecting the body 140, the hologram layer 420, and the ink layer 460 during the decoration process. Alternatively, the device 400 can be formed by performing an in-mold rolling process to combine the hologram layer 420 and the ink layer 460 with the body 140. In other embodiments, a hot stamping process, a lamination process, or a hot imprinting process can be adopted to adhering the film having the hologram layer 420 and the ink layer 460 on the body 140 to fabricate the device 400. Accordingly, the device 400 has both holographic patterns H and ink pattern.

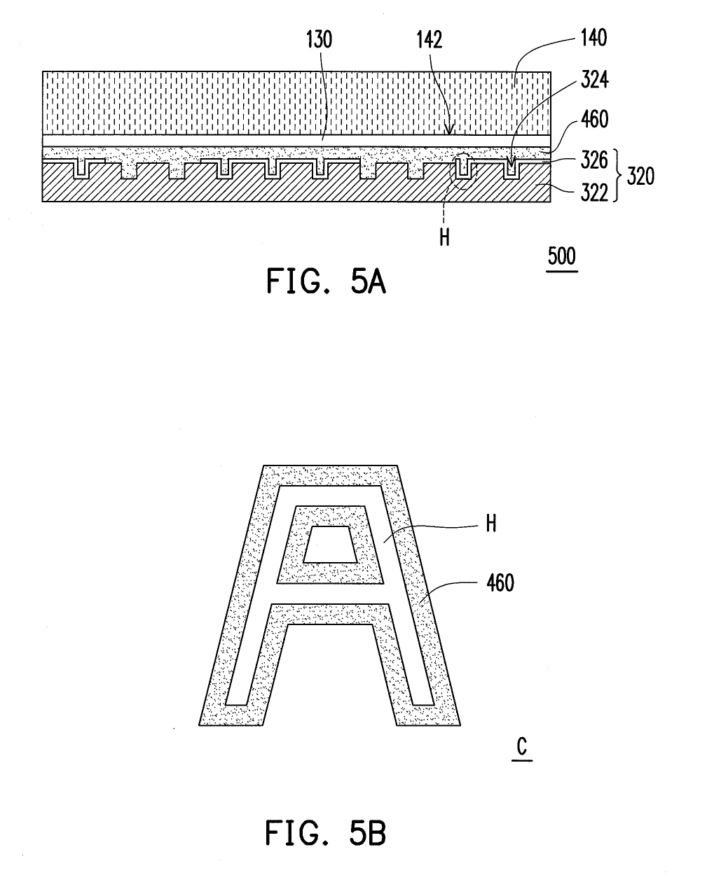

FIG. 5A illustrates a schematic cross sectional view of a decorated device according to further another embodiment and FIG. 5B illustrates a schematic top view of a complex holographic pattern. Referring to FIG. 5A, the manufacturing method of the device 500 combines the aforesaid process depicted in FIGS. 3A and 3B. In other words, the hologram layer 320 and the ink layer 460 are conformed adhered on the body 140 through the adhesive layer 130.

The holographic patterns H of the hologram layer 320 are partially distributed on the surface of the body 140 so that the ink layer 460 can be exposed by a portion of the uneven structure 324 without being covered by the reflective layer 326. Therefore, the holographic patterns H and the ink layer 460 together construct the complex holographic pattern C exemplified illustrated in FIG. 5B. When a user views the complex holographic pattern C, the partial holographic pattern H and a part of the ink layer 460 are seen. Nevertheless, the relative locations and the areas of the holographic patterns H and the ink layer 460 can be modified based on specific requirement to form the complex holographic pattern C, and the drawing illustrated in FIG. 5B is exemplified shown while the invention is not limited thereto. That is to say, under different designs, the device 500 can have kinds of patterns to present particular appearances.

In summary, the hologram layer of the invention is formed on a body of a device through a decoration process. The hologram layer is conformed to the surface of the body of the device so as to improve the variety of the design of the device. In addition, the holographic patterns constructed by the hologram layer are sandwiched between a transparent base layer and the body so as to prevent from the ambient destruction. Accordingly, the reliability and the lifetime of the hologram layer is improved so as to provide a better anti-forgery function.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decorated device comprising:
a body;
a hologram layer disposed on the body and comprising a transparent base layer having an uneven structure and a reflective layer substantially conformable covering the uneven structure to form a plurality of holographic patterns, wherein the reflective layer is located between the body and the transparent base layer; and
an adhesion layer disposed between a surface of the body and the hologram layer.

2. The decorated device according to claim 1, wherein the surface is a non-plane surface and the hologram layer is conformed to the non-plane surface.

3. The decorated device according to claim 1, wherein the transparent base layer is a durable layer.

4. The decorated device according to claim 1, wherein the transparent base layer is a releasing layer.

5. The decorated device according to claim 1, further comprising an ink layer disposed between the transparent base layer and the adhesion layer.

6. The decorated device according to claim 1, wherein a material of the reflective layer comprises Al, Cu, Ni, Zn, Cr, Ag, Ti, W, Au, Pt, Sn, Mg, Pb, metal oxide, alloy oxide, or any combination thereof.

7. A method of fabricating a decorated device comprising:
forming a hologram layer having a plurality of holographic patterns on a substrate;
forming an adhesion layer on the hologram layer away from the substrate; and
forming a body by an decoration process so that the hologram layer is conformably disposed on a surface of the body through the adhesion layer.

8. The method of fabricating a decorated device according to claim 7, wherein the method of forming the hologram layer on the substrate comprises:
forming a transparent base layer on the substrate;
performing a pattern transferring process on the transparent base layer to form an uneven structure away from the substrate; and
forming a reflective layer on the transparent base layer and the reflective layer conformably covering the uneven structure.

9. The method of fabricating a decorated device according to claim 8, wherein the method of performing the pattern transferring process on the transparent base layer comprises performing an embossing process on the transparent base layer to form the uneven structure away from the substrate.

10. The method of fabricating a decorated device according to claim 8, wherein the method of forming the reflective layer on the uneven structure comprises performing an evaporation coating process.

11. The method of fabricating a decorated device according to claim 8, wherein the method of forming the reflective layer on the uneven structure comprises performing a sputtering process.

12. The method of fabricating a decorated device according to claim 8, wherein the reflective layer is formed before forming the uneven structure on the transparent base layer.

13. The method of fabricating a decorated device according to claim 8, wherein the reflective layer is formed after forming the uneven structure on the transparent base layer.

14. The method of fabricating a decorated device according to claim 13, further comprising:
forming a mask layer on the base layer to cover a portion of the uneven structure before forming the reflective layer; and
removing the mask layer after forming the reflective layer so that the reflective layer exposes the portion of the uneven structure.

15. The method of fabricating a decorated device according to claim 7, wherein the method of the decoration process comprises:
putting the substrate and the hologram layer disposed thereon in a fixture;
filling a plastic material in the fixture;
ejecting the body and the hologram layer from the fixture; and
separating the substrate from the hologram layer.

16. The method of fabricating a decorated device according to claim 15, wherein the substrate is separated from the hologram layer simultaneously when the body and the hologram layer are ejected.

17. The method of fabricating a decorated device according to claim 15, wherein the substrate is separated from the hologram layer after the body and the hologram layer are ejected.

18. The method of fabricating a decorated device according to claim 7, wherein the decoration process comprises adhering the hologram layer on the surface of the body through performing an in-mold rolling process.

19. The method of fabricating a decorated device according to claim 7, further comprising forming an ink layer on the hologram layer before forming the adhesion layer.

20. The method of fabricating a decorated device according to claim 7, further comprising:
forming a releasing layer on the substrate before forming the hologram layer so that the releasing layer is located between the hologram and the substrate; and
separating the substrate and the releasing layer from the hologram layer after forming the body.
